(19) United States
(12) Patent Application Publication
(10) Pub. No.: US 2012/0038429 A1
(43) Pub. Date: Feb. 16, 2012

(54) Oscillator Circuits Including Graphene FET

(75) Inventors: Wilfried E. Haensch, Somers, NY (US); Yong Liu, Rye, NY (US); Zihong Liu, Yorktown Heights, NY (US)

(73) Assignee: INTERNATIONAL BUSINESS MACHINES CORPORATION, Armonk, NY (US)

(21) Appl. No.: 12/856,269

(22) Filed: Aug. 13, 2010

(51) Int. Cl. H03B 5/12

(52) U.S. Cl. 331/117 FE

(57) ABSTRACT

An oscillator circuit includes a field effect transistor (FET), the FET comprising a channel, source, drain, and gate, wherein at least the channel comprises graphene; an LC component connected to the FET, the LC component comprising at least one inductor and at least one capacitor; and a feedback loop connecting the FET source to the FET drain via the LC component.

### FIELD

This disclosure relates generally to the field of oscillator circuit configuration, and more specifically to use of a graphene field effect transistor (FET) in an oscillator circuit.

### DESCRIPTION OF RELATED ART

Graphene refers to a two-dimensional planar sheet of carbon atoms arranged in a hexagonal benzene-ring structure. A free-standing graphene structure is theoretically stable only in a two-dimensional space, which implies that a truly planar graphene structure does not exist in a three-dimensional space, being unstable with respect to formation of curved structures such as soot, fullerenes, nanotubes or buckled two dimensional structures. However, a two-dimensional graphene structure may be stable when supported on a substrate, for example, on the surface of a silicon carbide (SiC) crystal. Free standing graphene films have also been produced, but they may not have the idealized flat geometry.

Structurally, graphene has hybrid orbitals formed by sp² hybridization. In the sp² hybridization, the 2s orbital and two of the three 2p orbitals mix to form three sp² orbitals. The one remaining p-orbital forms a pi (π)-bond between the carbon atoms. Similar to the structure of benzene, the structure of graphene has a conjugated ring of the p-orbitals, i.e., the graphene structure is aromatic. Unlike other allotropes of carbon such as diamond, amorphous carbon, carbon nanofoam, or fullerenes, graphene is only one atomic layer thin.

Graphene has an unusual band structure in which conical electron and hole pockets meet only at the K-points of the Brillouin zone in momentum space. The energy of the charge carriers, i.e., electrons or holes, has a linear dependence on the momentum of the carriers. As a consequence, the carriers behave as relativistic Dirac-Fermions with a zero effective mass and are governed by Dirac's equation. Graphene sheets may have a large carrier mobility of greater than 200,000 cm²/V-sec at 4K. Even at 300K, the carrier mobility can be higher than 15,000 cm²N-sec.

Graphene layers may be grown by solid-state graphitization, i.e., by sublimating silicon atoms from a surface of a silicon carbide crystal, such as the (0001) surface. At about 1,150° C., a complex pattern of surface reconstruction begins to appear at an initial stage of graphitization. Typically, a higher temperature is needed to form a graphene layer. Graphene layers on another material are also known in the art. For example, single or several layers of graphene may be formed on a metal surface, such as copper and nickel, by chemical deposition of carbon atoms from a carbon-rich precursor.

Graphene displays many other advantageous electrical properties such as electronic coherence at near room temperature and quantum interference effects. Ballistic transport properties in small scale structures are also expected in graphene layers.

While single-layer graphene sheet has a zero band-gap with linear energy-momentum relation for carriers, two-layer graphene, i.e. bi-layer graphene, exhibits drastically different electronic properties, in which a band gap may be created under special conditions. In a bi-layer graphene, two graphene sheets are stacked on each other with a normal stacking distance of roughly 3.35 angstrom, and the second layer is rotated with respect to the first layer by 60 degree. This stacking structure is the so-called A-B Bernel stacking, and is also the graphene structure found in natural graphite. Similar to single-layer graphene, bi-layer graphene has zero-band gap in its natural state. However, by subjecting the bi-layer graphene to an electric field, a charge imbalance can be induced between the two layers, and this will lead to a different band structure with a band gap proportional to the charge imbalance.

Field effect transistors (FETs) based on graphene have shown high mobility, with cut-off frequencies beyond 100 gigahertz (GHz), outperforming traditional semiconductor devices such as silicon MOSFETs. Graphene FETs may also have relatively low noise. Therefore, graphene FETs are promising components for use in radio-frequency (RF) electronics.

### SUMMARY

In one aspect, an oscillator circuit includes a field effect transistor (FET), the FET comprising a channel, source, drain, and gate, wherein at least the channel comprises graphene; an LC component connected to the FET, the LC component comprising at least one inductor and at least one capacitor; and a feedback loop connecting the FET source to the FET drain via the LC component.

In one aspect, a method for providing an oscillation in an oscillator circuit includes connecting a source of a field effect transistor (FET) to a drain of the FET via an LC component, wherein the FET comprises a channel, source, drain, and gate, wherein at least the channel comprises graphene, and wherein the LC component comprises at least one inductor and at least one capacitor.

Additional features are realized through the techniques of the present exemplary embodiment. Other embodiments are described in detail herein and are considered a part of what is claimed. For a better understanding of the features of the exemplary embodiment, refer to the description and to the drawings.

### BRIEF DESCRIPTION OF THE SEVERAL VIEWS OF THE DRAWINGS

Referring now to the drawings wherein like elements are numbered alike in the several FIGURES:

FIG. 1 illustrates an embodiment of an oscillator circuit including a graphene FET.

FIG. 2 illustrates another embodiment of an oscillator circuit including a graphene FET.

FIG. 3 illustrates another embodiment of an oscillator circuit including a graphene FET.

FIG. 4 illustrates another embodiment of an oscillator circuit including dual graphene FETs.

FIG. 5 illustrates an embodiment of an oscillator circuit including a graphene FET.

### DETAILED DESCRIPTION

Embodiments of an oscillator including a graphene FET are provided, with exemplary embodiments being discussed below in detail. High-frequency oscillator circuits, with an output frequency in the range of GHz or higher, are basic components in many electronic systems, such as RF transmitters and receivers. Oscillators based on silicon (Si) or gallium arsenide (GaAs) FETs may operate at frequencies in the range of GHz, but suffer from high noise, significant nonlinearity, poor reliability, and relatively low cutoff frequency limits. However, use of a graphene FET (i.e., a FET in which at least the FET channel is made of graphene) in an oscillator circuit may provide an oscillator with an output frequency beyond tens of GHz (beyond 100 GHz in some embodiments) with good reliability, as graphene FETs exhibit high mobility, good linearity, and relatively low noise. A graphene FET also has a higher cut-off frequency than a silicon-based FET. The oscillation may be provided by operating the graphene FET in saturation mode, and through use of a feedback loop connecting the FET drain to the FET source via an LC component.

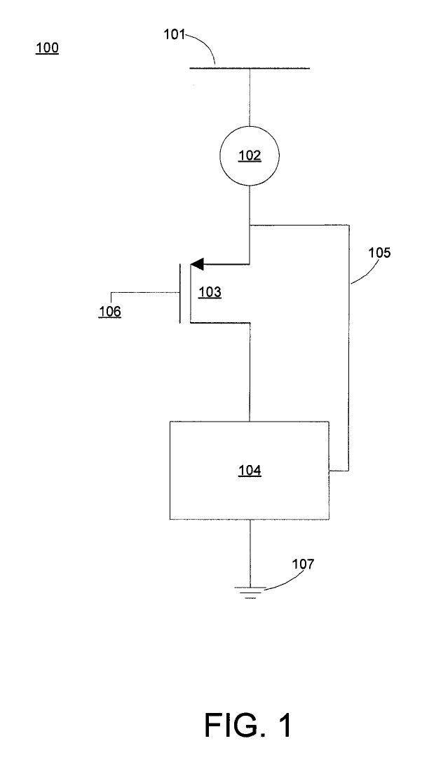

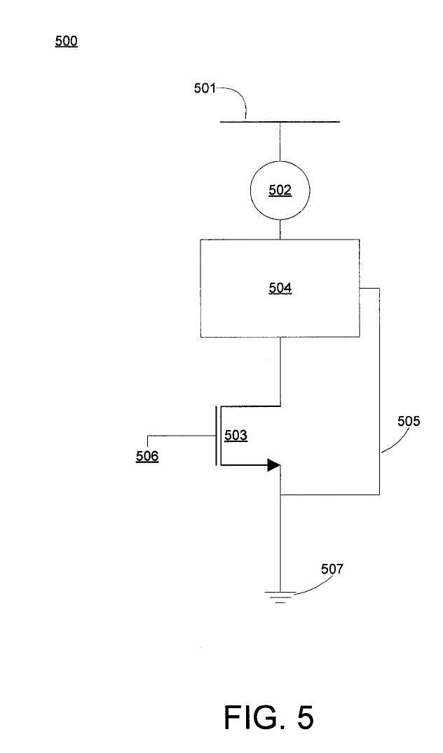

FIG. 1 illustrates an embodiment of an oscillator circuit 100 including a graphene FET 103. Graphene FET 103 has a relatively high cutoff frequency and can operate in the current saturation mode. Line voltage 101 and bias current source 102 are connected to the source of graphene FET 103. The gate of graphene FET 103 is connected to node 106, which may be ground or a direct current (DC) voltage source in various embodiments. The drain of graphene FET 103 is connected to LC component 104. LC component 104 acts as a frequency-selective network, and may include one or more inductors and one or more capacitors; any appropriate arrangement and number of inductors and capacitors may comprise LC component 104 in various embodiments. LC component 104 is connected to ground connection 107. A feedback loop 105 connects the drain of graphene FET 103 to the source of graphene FET 103 via LC component 104. The gain provided by feedback loop 105 causes an oscillation in the circuit. Graphene FET 103 as shown in FIG. 1 is a p-type graphene FET; in other embodiments of an oscillator circuit including a graphene FET, an n-type graphene FET may be substituted for a p-type graphene FET (discussed in further detail below with respect to FIG. 5).

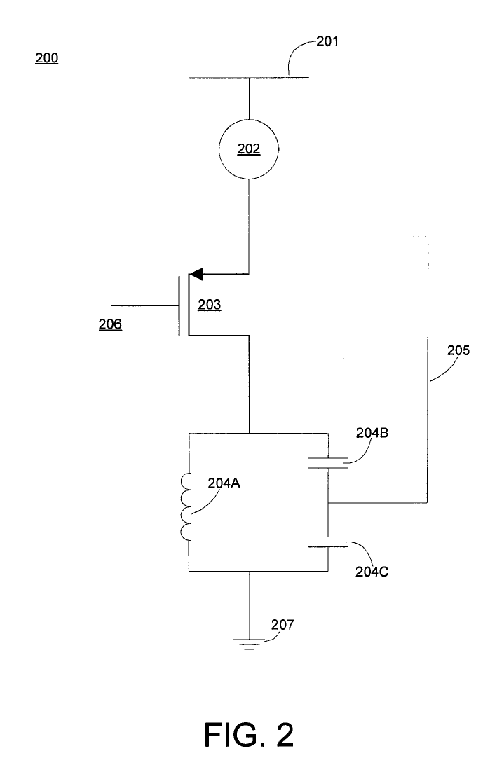

FIG. 2 illustrates an embodiment of an oscillator circuit 200 including a graphene FET 203, in which LC component 104 of FIG. 1 is embodied as inductor 204A in parallel with capacitors 204B-C in series. Graphene FET 203 has a relatively high cutoff frequency and can operate in the current saturation mode. Line voltage 201 and bias current source 202 are connected to the source of graphene FET 203. The gate of graphene FET 203 is connected to node 206, which may be ground or a DC voltage source in various embodiments. The drain of graphene FET 203 is connected to inductor 204A in parallel with series capacitors 204B and 204C. Inductor 204A and capacitor 204C are connected to ground connection 207. Feedback loop 205 is connected from between series capacitors 204A and 204B to the source of graphene FET 203. The gain provided by feedback loop 205 causes an oscillation in the circuit. Assuming inductor 204A has an inductance L, capacitor 204B has a capacitance C1, and capacitor 204C has a capacitance C2, the frequency (f) of the oscillation provided by oscillator circuit 200 is given by:

f=1/(2π{square root over ((L(C1*C2)/(C1+C2)))}). EQ. 1

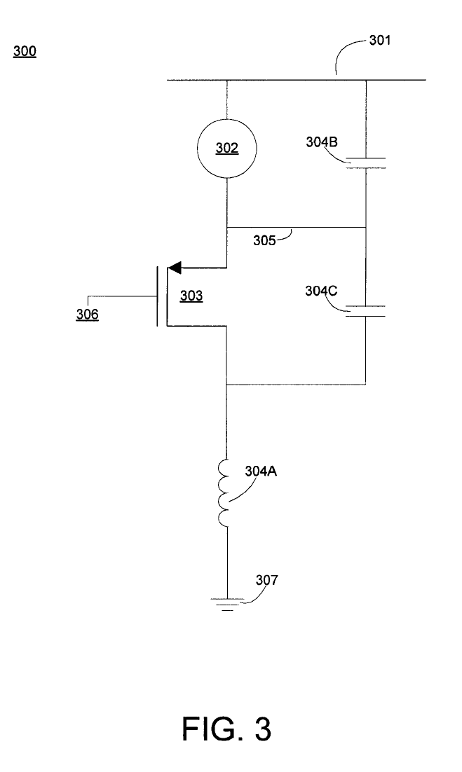

FIG. 3 illustrates an embodiment of an oscillator circuit 300 including a graphene FET 303, in which LC component 104 of FIG. 1 is embodied as inductor 304A and capacitors 304B-C. Graphene FET 303 has a relatively high cutoff frequency and can operate in the current saturation mode. Line voltage 301 and bias current source 302 are connected to the source of graphene FET 303. The gate of graphene FET 303 is connected to node 306, which may be ground or a DC voltage source in various embodiments. The drain of graphene FET 303 is connected to inductor 304A. Inductor 304A is also connected to ground connection 307. Capacitor 304B is connected from line voltage 301 to feedback loop 305, and capacitor 304C is connected from the drain of graphene FET 303 to feedback loop 305. Feedback loop 305 is connected from between capacitors 304A and 304B to the source of graphene FET 303. The gain provided by feedback loop 305 causes an oscillation in the circuit. Assuming inductor 304A has an inductance L, capacitor 304B has a capacitance C1, and capacitor 304C has a capacitance C2, the frequency (f) of the oscillation provided by oscillator circuit 300 is given by:

f=1/(2π{square root over ((L(C1*C2)/(C1+C2)))}). EQ. 2

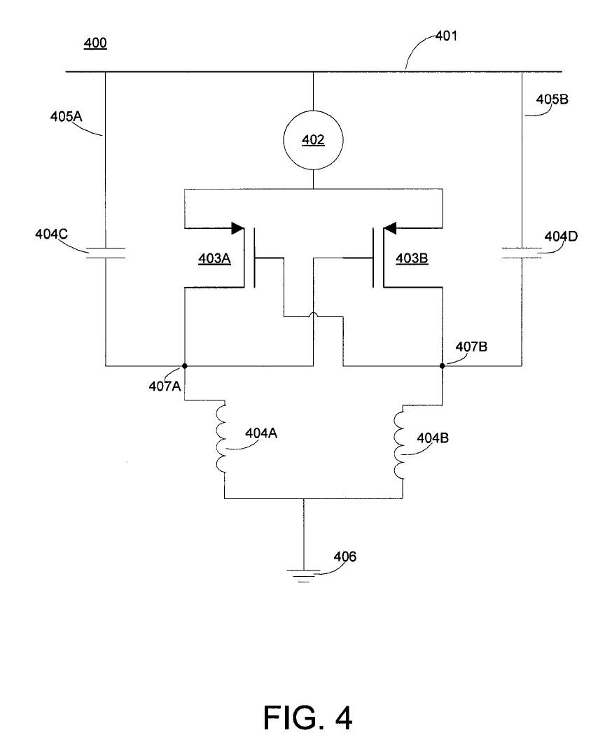

FIG. 4 illustrates an embodiment of an oscillator circuit 400 including dual graphene FETs 403A-B. Oscillator circuit 400 is a differential circuit. Graphene FETs 403A-B each have a relatively high cutoff frequency and can operate in the current saturation mode. Line voltage 401 and bias current source 402 are connected to the source of graphene FET 403A and to the source of graphene FET 403B. The drain of graphene FET 403A and the gate of grapheme FET 403B are connected to capacitor 404C and inductor 404A via junction 407A, and the drain of graphene FET 403B and the gate of grapheme FET 403A are connected to capacitor 404D and inductor 404B via junction 407B. Inductors 404A-B are connected to ground connection 406. Capacitors 404C-D are connected to line voltage 401 via feedback loops 405A-B, respectively. The signal provided by feedback loops 405A-B to line voltage 401 is fed back into the respective sources of graphene FETs 403A-B via bias current source 402. The gain provided by feedback loops 405A-B causes an oscillation in the circuit. In an embodiment in which the inductance of inductors 404A-B are each about 0.5 nanohenries (nH), and the capacitance of capacitors 404C-D are each about 0.5 femtofarads (fF), the frequency f of the oscillation of oscillator circuit 400 may be about 100 GHz. Assuming inductor 404A and inductor 404B each have an inductance L, and capacitor 404C and capacitor 404D each have a capacitance C, the frequency (f) of the oscillation of oscillator circuit 400 is given by:

f=1/(2π\sqrt{(LC)}). EQ. 3

FIG. 5 illustrates an embodiment of an oscillator circuit 500 including a graphene FET 503. Graphene FET 503 is an n-type FET. Graphene FET 503 has a relatively high cutoff frequency and can operate in the current saturation mode. Line voltage 501 and bias current source 502 are connected to LC component 504. LC component 504 acts as a frequency-selective network, and may include one or more inductors and one or more capacitors; any appropriate arrangement and number of inductors and capacitors may comprise LC component 504 in various embodiments. LC component 504 is connected the drain of graphene FET 503. The gate of graphene FET 503 is connected to node 506, which may be ground or a DC voltage source in various embodiments. The source of graphene FET 503 is connected to ground connection 507. Feedback loop 505 connects the drain of graphene FET 503 to the source of graphene FET 503 via LC component 504. The gain provided by feedback loop 505 causes an oscillation in the circuit.

The technical effects and benefits of exemplary embodiments include a reliable oscillator circuit that provides an oscillation having a relatively high frequency for use in an electronic system.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. An oscillator circuit, comprising:
a field effect transistor (FET), the FET comprising a channel, source, drain, and gate, wherein at least the channel comprises graphene;
an LC component connected to the FET, the LC component comprising at least one inductor and at least one capacitor; and
a feedback loop connecting the FET source to the FET drain via the LC component.

2. The oscillator circuit of claim 1, wherein the FET gate is connected to one of a ground connection and a direct current (DC) voltage source.

3. The oscillator circuit of claim 1, wherein the FET operates in current saturation mode.

4. The oscillator circuit of claim 1, wherein the LC component comprises an inductor in parallel with a first capacitor and a second capacitor in series, wherein the FET drain is connected between the inductor and the first capacitor, and wherein the feedback loop connects from between the first capacitor and the second capacitor to the FET source.

5. The oscillator circuit of claim 4, wherein the inductor has an inductance L, the first capacitor has a capacitance C2, and the second capacitor has a capacitance of C1, and wherein a frequency (f) of an oscillation of the oscillator circuit is given by:
f=1/(2π{square root over ((L(C1*C2)/(C1+C2)))}).

6. The oscillator circuit of claim 4, wherein a ground connection is connected between the inductor and the second capacitor, and further comprising a voltage line and a bias current source connected to the FET source.

7. The oscillator circuit of claim 1, wherein the LC component comprises a first inductor connected from the FET drain to a ground connection, a first capacitor connected from the FET drain to the FET source by the feedback loop, and a second capacitor connected from the first capacitor and the feedback loop to a voltage line.

8. The oscillator circuit of claim 7, wherein the inductor has an inductance L, the first capacitor has a capacitance C2, and the second capacitor has a capacitance of C1, and wherein a frequency (f) of an oscillation of the oscillator circuit is given by:
f=1/(2π{square root over ((L(C1*C2)/(C1+C2)))}).

9. The oscillator circuit of claim 7, further comprising a bias current source connected between the voltage line and the FET source.

10. The oscillator circuit of claim 1, wherein the FET comprises a first FET and a second FET, each of the first FET and the second FET comprising a channel, source, drain, and gate, and wherein at least the channel comprises graphene.

11. The oscillator circuit of claim 10, wherein the LC component comprises a first inductor connected between the drain of the first FET and a ground connection, a second inductor connected between the drain of the second FET and the ground connection, a first capacitor connected between the drain of the first FET and the voltage line, and a second capacitor being connected between a drain of the second FET and the voltage line.

12. The oscillator circuit of claim 11, further comprising a bias current source connected between the voltage line and the source of the first FET, and between the voltage line and the source of the second FET.

13. The oscillator circuit of claim 11, wherein the gate of the first FET is connected to the second capacitor, and the gate of the second FET is connected to the first capacitor.

14. The oscillator circuit of claim 11, wherein each of the first and second inductor have an inductance L, wherein each of the first and second capacitors have a capacitance C, and wherein a frequency (f) of an oscillation of the oscillator circuit is given by:
f=1/(2π\sqrt{(LC)}).

15. The oscillator circuit of claim 1, wherein the FET comprises a p-type FET, wherein a voltage line and a bias current source are connected to the source of the FET, and wherein the drain of the FET is connected to a ground connection via the LC component.

16. The oscillator circuit of claim 1, wherein the FET comprises an n-type FET, wherein the source of the FET is connected to a ground connection, and wherein a voltage line and a bias current source are connected to the drain of the FET via the LC component.

17. A method for providing an oscillation in a graphene oscillator circuit, the method comprising:
connecting a source of a field effect transistor (FET) to a drain of the FET via an LC component, wherein the FET comprises a channel, source, drain, and gate, wherein at least the channel comprises graphene, and wherein the LC component comprises at least one inductor and at least one capacitor.

18. The method of claim 17, further comprising operating the FET in saturation.

19. The method of claim 17, further comprising connecting the gate of the FET to one of a ground connection and a direct current (DC) voltage source.
